(19) United States
(12) Patent Application Publication
(10) Pub. No.: US 2016/0103157 A1
(43) Pub. Date: Apr. 14, 2016

(54) RATIO METRIC CURRENT MEASUREMENT

(71) Applicant: James J. Kinsella, Brentwood, TN (US)

(72) Inventor: James J. Kinsella, Brentwood, TN (US)

(21) Appl. No.: 14/971,939

(22) Filed: Dec. 16, 2015

Related U.S. Application Data
(63) Continuation of application No. 14/037,922, filed on Sep. 26, 2013.

(51) Int. Cl. G01R 19/00; H02H 3/08

(52) U.S. Cl. CPC G01R 19/0092; H02H 3/08

(57) ABSTRACT

The total current flow in a given electric circuit path is estimated by measuring the current in a second parallel current path and applying a ratio of the conductivity of the main and secondary path. Earth leakage current is measured by passing three wires through a toroid so as to detect differential current flow. Each wire is a conduction path wire parallel to each phase cable. The relative harmonic content between the fundamental and higher frequency components of a load current are calculated using a conduction path parallel to the main power cables.

### CROSS-REFERENCE TO RELATED APPLICATION

This application claims priority to U.S. application Ser. No. 14/037,922 filed Sep. 26, 2013 and entitled “RATIO METRIC CURRENT MEASUREMENT,” and which is incorporated herein in its entirety by this reference.

### FIELD OF THE INVENTION

The present disclosure relates in general to electric motor control and distribution of electrical energy and more particularly to a ratio metric current measurement.

### BACKGROUND OF THE INVENTION

The measurement of AC electrical current is frequently required in the electric motor industry. Some uses of electrical current measurement include metering, short circuit protection, motor overload protection, branch circuit overload, harmonic measurement, and the like. Of particular interest are current measurements of high bandwidth currents in electric motors and/or high current levels that are expensive to measure using conventional current measurement schemes.

There are many methods of making these current measurements. These include precision shunt resistors, current transformers, Hall Effect devices, resistive measurement, and the like.

With all of these methods, the size and cost of the current measurement device goes up geometrically with the magnitude of the measured current and the bandwidth of that current measurement.

### BRIEF DESCRIPTION OF THE DRAWINGS

For a more complete understanding of the present disclosure, reference is made to the following description, taken in conjunction with the accompanying drawings, wherein like reference numerals represent like parts, in which:

FIG. 1 illustrates a main load cable and a high impedance wire connected at two points of the main load cable;

FIG. 2 illustrates an assembly having one phase of what would be a three phase branch circuit with the main load cable and the high impedance wire connected with a main power supply and a load such as an electric motor;

FIG. 3 illustrates an assembly with a toroid through which high impedance wires carrying the ratio currents from each phase of a three phases are passed.

### DETAILED DESCRIPTION

### Known Parallel Impedances

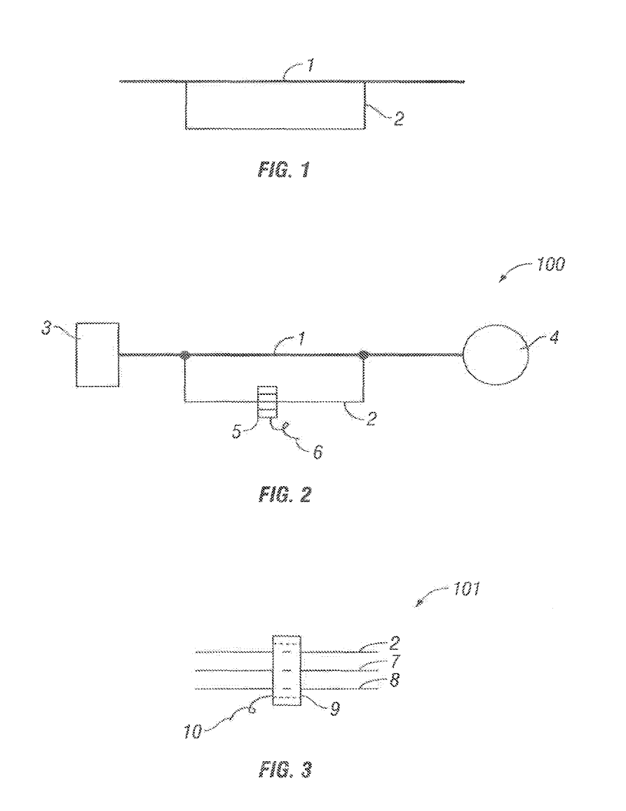

FIG. 1 illustrates a main load cable 1 and a high impedance wire 2 connected at two points of the main load cable 1 such that any current flow will divide proportional to the impedances of the two paths per Ohms Law. If electrical current is divided between two or more parallel conduction paths, that current will divide according to the respective impedances of these paths. That division will remain consistent as long as the relative impedances remain consistent. Thus the current in the sum of the parallel paths can be calculated by knowing the current in one path and the impedances of the other parallel paths. In one implementation, a secondary higher impedance path would be made in parallel to a main current carrying path. The secondary path and the main path could have a known impedance ratio or a known current could be driven through both paths and the impedance ratio could be calibrated via the known total current and stored. Similarly, a calibration step could be employed wherein the impedance of one of the paths could be modified to achieve a known impedance ratio. A further calibration implementation is to induce a known current into the main low impedance connection where the high impedance current would always reflect that value or ratio. For an actual application, the calibration could be made directly from a known motor current. A further option is to begin with an estimated ratio, then, with a suitable algorithm, learn the correct ratio, during commissioning or in service.

Once the impedance or current division ratio is known, calibrated, or learned, the total current in the sum of the paths can be ascertained by measuring the current in the secondary path. This has the advantage of allowing the use of smaller and less expensive current measurement elements.

Unknown Parallel Impedances

In some current measurements, the important 10 measurements to be made are the high frequency components of the current. In many cases, these high frequency components are in a known ratio to the fundamental AC current. This is true for detecting arc faults, pump cavitation, and motor bearing failure, among others. In this case, the current spectrum is separated into the various frequencies and the high frequency components are compared, in ratio, to the mains fundamental.

This means that a parallel conduction path contains all of the information required to detect the required event even though all of the current does not flow through the current sensor. In fact, it is unnecessary to know the precise division of the current between the parallel paths, since each path contains the same ratio metric information.

The advantages of this measurement are several. First, smaller and less expensive current sensors may be used to gather the same information as conventional measurement techniques. Second, smaller sensors generally have a higher bandwidth than larger sensors. This is especially true of Hall Effect magnetic path nulling sensors (LEM's). Third, the power supply requirements of the sensors can be reduced. This is because LEM nulling type sensors consume power in proportion to the measured current.

In one implementation of this technology, a secondary path is made parallel to the main current path. A small sensor, a LEM or similar, is positioned in the secondary path. The current is measured in this secondary path. This current is expanded into its various frequency components. A detection algorithm then compares the frequencies of interest in ratio to the magnitude of the fundamental.

Motor Branch Circuit Protection

FIG. 2 shows an assembly 100 having one phase of what would be a three phase branch circuit with the main load cable 1 and the high impedance wire 2 connected with a main power supply 3 and a load 4 such as an electric motor. A sensor 5 on the high impedance wire 2 is used for measuring a current proportional to the load current. This current is observed through output 6. A processor (not shown) may be used in conjunction with the sensor to perform the current measurements and calculations.

This measurement lends itself to providing motor overload protection either by protection thresholds or more complex motor modeling techniques. The current measured in FIG. 2 may be used for motor and installed cable thermal protection as well as an indicator of motor load and may also be used for metering and monitoring. Should a fault occur in the branch circuit, this current may be used for measuring the rate of rise of line current and sending a trip signal to a circuit breaker. Cable or motor insulation faults are common and occur through failure of insulation. These faults are progressive in the sense that insulation fails over a period of time. When detected early, costly repairs and down time are minimized.

FIG. 3 shows an assembly 101 with three high impedance wires 2, 7, and 8, from a three phase application of FIG. 1, passed through a toroid 9. In the absence of a current path to ground, the instantaneous value of three balanced line currents is zero. Thus by passing all three phase currents through the toroid 9 and measuring the out of balance (known as the differential or earth leakage current), the output 10 reflects the degree of current leakage to ground or the degree of imbalance in the line currents. The output 10 is processed by a variety of electronic means so that the equipment user can respond accordingly.

Leakage currents to ground can be relatively constant when caused by insulation degradation or may be relatively intermittent in the event of arcing in cables to ground or within the motor. When such arcing occurs, the output, which contains the full spectrum of line current frequencies, allows for further processing to provide information regarding the system arc energy.

Although the present disclosure has been described in detail with reference to particular embodiments, it should be understood that various other changes, substitutions, variations, alterations, and modifications may be ascertained by those skilled in the art and it is intended that the present disclosure encompass all such changes, substitutions, variations, alterations, and modifications as falling within the spirit and scope of the appended claims. Moreover, the present disclosure is not intended to be limited in any way by any statement in the specification that is not otherwise reflected in the appended claims.

What is claimed is:

1. A method of monitoring the magnitude of an electric current flowing in a main conducting path of a circuit during the circuit's operation, by continuously sensing only a fraction of the current to be monitored, said method comprising:
dividing at least a portion of the main conducting path of the circuit into a primary conducting path and a secondary conducting path, the primary and secondary conducting paths being in parallel with one another;
predetermining a ratio that substantially defines what portion of a current flowing in the main conducting path will flow into the primary conducting path and what portion of the current flowing in the main conducting path will flow into the secondary conducting path;
coupling a current sensor to the secondary conducting path to continuously sense the magnitude of current presently flowing in the secondary path; and
inferring a total magnitude of current presently flowing in the main conducting path of the circuit based on said sensed magnitude of current, said inferring further comprising:
determining the magnitude of the current presently flowing in the primary conducting path from the magnitude of the sensed current and the predetermined current ratio; and
adding the determined magnitude of the current presently flowing in the primary conducting path to the sensed magnitude of the current presently flowing in the secondary path.

2. The method of claim 1, wherein the predetermined current ratio is established based on a known impedance ratio between impedances of the primary conducting path and the secondary conducting path.

3. The method of claim 2, wherein the known impedance ratio can be inferred from dividing the main conducting path of the circuit into the primary conducting path and the secondary conducting path in accordance with a known physical proportion.

4. The method of claim 2, wherein said determining a ratio further comprises:
introducing a current of known magnitude into the main conducting path;
sensing the magnitude of that portion of the known current that is flowing in the secondary path; and
inferring the magnitude of that portion of the known current flowing in the primary conducting path as the magnitude of the known current amount less the magnitude of the sensed portion.

5. The method of claim 1, wherein the main conducting path of the circuit is coupled to a motor, and the known current is a load current drawn by the motor during its operation.

6. The method of claim 1, wherein the impedance of the secondary conducting path is substantially greater than the impedance of the primary conducting path.

7. The method of claim 2, wherein said predetermining a current ratio further comprises: estimating the ratio of the impedances of the primary conducting path and the secondary conducting path from test data.

8. The method of claim 7, wherein the estimated current ratio is refined by a learning process during commissioning of the circuit or while the circuit is in service.

9. The method of claim 1, wherein the main conducting path of the circuit is coupled to a load, said method further comprising actuating a circuit protection device whenever the amount of inferred current presently flowing in the main conducting path exceeds a magnitude that indicates the presence of a fault condition.

10. The method of claim 9, wherein the circuit protection device is a circuit breaker.

11. The method of claim 9, further comprising:
processing the sensed current to determine a rate of increase in the magnitude of the current presently flowing in the secondary path; and
actuating the circuit protection device whenever the rate of increase exceeds a magnitude that can result from the presence of a fault condition.

12. The method of claim 1, wherein:
the circuit includes at least three of the main conducting paths, each of the main conducting paths being coupled to a motor,
the current sensor is a toroid having an output coupled to a circuit protection device, each of the secondary conducting paths being coupled to the toroid, and
the method further comprising actuating the circuit protection device when the toroid detects an imbalance in the current presently flowing in the secondary conducting paths of each of the at least three conducting paths of the circuit, the imbalance being indicative of the presence of a fault condition.

13. A method of monitoring the magnitude of a ratio between high-frequency components and a fundamental component of an electric current flowing in a main conducting path of a circuit during the circuit's operation, by continuously sensing only a fraction of the current for which the magnitude is to be monitored, said method comprising:
dividing at least a portion of the main conducting path of the circuit into a primary conducting path and a secondary conducting path, the primary and secondary conducting paths being in parallel with one another;
predetermining a nominal magnitude ratio between a plurality of high frequency components and a fundamental component of, the current flowing in the main conducting path;
coupling a current sensor to the secondary conducting path to continuously sense and output the magnitudes of the high frequency and fundamental components of the current presently flowing in the secondary path;
processing the output from the current sensor to continuously derive a magnitude ratio for the current presently flowing in the conducting path; and
when the derived magnitude ratio exceeds the nominal magnitude ratio by a predetermined threshold indicating the presence of a fault condition, opening the circuit conducting path to halt operation of the circuit.

14. The method of claim 13, wherein said predetermining a nominal magnitude ratio further comprises:
sensing a nominal current flowing in the main conducting path when the circuit is operating normally with no fault conditions present;
expanding the sensed nominal current into its various frequency components; and
comparing the magnitude of high frequency current components of the sensed nominal current to the magnitude of the fundamental component of the sensed nominal current.

15. The method of claim 13, wherein said processing further comprises:
expanding the sensed current presently flowing in the secondary path into its various frequency components; and
comparing the magnitude of high frequency current components of the current presently flowing in the secondary path to the magnitude of the fundamental component of the current presently flowing in the secondary path.

16. The method of claim 13, wherein the fault condition indicated by the predetermined threshold is for detecting at least one of: an arc fault, a pump cavitation, and a motor bearing failure.

17. A current monitoring apparatus for monitoring the magnitude of an electric current flowing in a main conducting path of a circuit during the circuit's operation, said monitoring circuit sensing only a fraction of the current to be monitored, said circuit comprising:
a secondary conducting path conductively coupled at two points along the conducting path of the circuit, the portion of the main conducting path of the circuit falling between the two points forming a primary conducting path that is in parallel with the secondary conducting path;
a current sensor coupled to the secondary conducting path to continuously sense the magnitude of current presently flowing in the secondary path; and
a processing device coupled to an output of the current sensor, wherein the processing device is configured to infer a total magnitude of current presently flowing in the main conducting path of the circuit based on the sensed amount of current and a predetermined ratio that substantially defines what portion of a current flowing in the main conducting path will flow into the primary conducting path and what portion of the current flowing in the main conducting path will flow into the secondary conducting path.

18. The current monitoring apparatus of claim 17, wherein:
the main conducting path of the circuit is coupled to a load,
the current monitoring apparatus further comprising a circuit protection device for interrupting the flow of current in the circuit,
the circuit protection device being coupled to the processor and is actuated by the processor whenever the amount of inferred current presently flowing in the main conducting path exceeds a magnitude that indicates the presence of a fault condition.

19. The current monitoring apparatus of claim 17, wherein the processor is further configured to process at least one of: the sensed current, the inferred current, to determine a rate of increase in the magnitude of the current presently flowing in the main path, the processor being configured to actuate the circuit protection device whenever the rate of increase exceeds a magnitude that can result from the presence of a fault condition.

20. The current monitoring apparatus of claim 17, wherein said determining a ratio further comprises:
introducing a current of known magnitude into the main conducting path;
sensing the magnitude of that portion of the known current that is flowing in the secondary path; and
inferring the magnitude of that portion of the known current flowing in the primary conducting path as the magnitude of the known current amount less the magnitude of the sensed portion.
